(19) United States
(12) Patent Application Publication
(10) Pub. No.: US 2003/0119301 A1
(43) Pub. Date: Jun. 26, 2003

(54) Method of fabricating an IMD layer to improve global planarization in subsequent CMP

(76) Inventors: Chen-Chiu Hsue, Hsinchu (TW); Shyh-Dar Lee, Hsinchu Hsien (TW)

Correspondence Address: BIRCH STEWART KOLASCH & BIRCH, PO BOX 747, FALLS CHURCH, VA, 22040-0747, US

(21) Appl. No.: 10/022,549

(22) Filed: Dec. 20, 2001

(51) Int. Cl. H01L 21/4763

(52) U.S. Cl. 438/620

(57) ABSTRACT

A method of fabricating an IMD layer is provided on a semiconductor substrate, on which at least two adjacent metal wiring lines separated by a gap are patterned. A first dielectric layer, preferably of silicon oxide, is formed on the metal wiring lines to partially fill the gap below the level of the top of the metal wiring lines using high density plasma chemical vapor deposition (HDPCVD). Then, a second dielectric layer, preferably of silicon oxide, is formed on the first dielectric layer to completely fill the gap to a predetermined thickness using PECVD. Thus, the first dielectric layer and the second dielectric layer between the two adjacent metal wiring lines serve as the IMD layer.

### BACKGROUND OF THE INVENTION

1. Field of the Invention

The present invention relates to a method of fabricating an inter-metal dielectric (IMD) layer. More particularly, the present invention relates to a method of fabricating an IMD layer to improve global planarization during subsequent chemical-mechanical polishing (CMP).

2. Description of the Related Art

In the fabrication of ultra-large-scale integration (ULSI) circuits, a plurality of metal wiring circuits, serving as vertical stacking or integration of multilevel interconnections, is used to increase circuit performance and the functional complexity of the circuits. An inter-metal dielectric (IMD) layer, typically of silicon oxide and deposited via a chemical vapor deposition (CVD) technique, is required to completely fill the gap between adjacent metal wiring lines, to be resistant to moisture transport, and to provide a low dielectric constant for minimizing capacitance between adjacent metal wiring lines. Thus, it is important to modify a deposition to obtain a high quality and void-free IMD layer. In addition, the IMD layer is required to provide a planarized surface as a successive layer in subsequent processes. In conventional technique, chemical-mechanical polishing (CMP) has gained significant popularity in planarizing wafer surfaces in preparation for subsequent fabrication. However, the issue of the loss of topological planarity on the IMD layer, resulting from different pattern densities, must be overcome. Therefore, it is also important to modify a deposition process to form an IMD layer with a preferred topography that is not sensitive to the CMP process, thus improving global planarization on the IND layer after CMP.

Referring to FIGS. 1A to 1D, U.S. Pat. No. 6,117,345 discloses a method in which high density plasma chemical vapor deposition (HDPCVD) is employed to form the IMD layer between the metal wiring lines. As shown in FIG. 1A, on a semiconductor substrate 10, a surface layer 12, a wiring layer 14, a protection layer 16 and a cap layer 18 are sequentially provided. Also, a photoresist layer 20 is patterned on the cap layer 18 to expose predetermined regions 22. As shown in FIG. 1B, using the photoresist layer 20 as a mask for etching the cap layer 18, the protection layer 16, the wiring layer 14 and the surface layer 12, a plurality of gaps 26 are formed in the exposed regions 22 respectively. At the same time, the wiring layer 14 is patterned as individual metal wiring lines 24 spaced from the gaps 26.

Next, the HDPCVD process, at a sufficiently high etch-to-deposition ratio is performed to form a HDPCVD oxide layer 28. At the early stage of the HDPCVD, as shown in FIG. 1C, the corner of the cap layer 18 is etched away, thus a taper topography of the HDPCVD oxide layer 28 is produced on the top of the cap layer 18. Then, as shown in FIG. 1D, the HDPCVD process is continually performed until the gaps 26 are filled with the HDPCVD oxide layer 28 reaching the level of the top of the protective layer 16, thus a flat topography of the HDPCVD oxide layer 28 is produced in the gaps 42. Next, using plasma-enhanced chemical vapor deposition (PECVD), a PECVD oxide layer 29 is deposited on the entire surface of the HDPCVD oxide layer 28.

However, a long process time is needed to completely fill the gaps 26 with the HDPCVD oxide layer 28 reaching the level of the top of the protective layer 16. This increases production costs and lowers throughput. As well, according to the taper and flat topography of the HDPCVD oxide layer 28, the top surface of the PECVD oxide layer 29 appears the corresponding topography. The pattern density of the taper topography of the PECVD oxide layer 29 causes different step heights, and becomes sensitive to subsequent CMP. This causes defects on the PECVD oxide layer 29 after the CMP. Thus, a modified method of fabricating the IMD layer, solving the aforementioned problems is called for.

### SUMMARY OF THE INVENTION

The present invention is a method of fabricating an IMD layer within a gap between adjacent metal wiring lines, that can form the IMD layer with a preferred topography that is not sensitive to subsequent CMP, thus improving the global planarization on the IMD layer.

The method of fabricating an IMD layer is provided on a semiconductor substrate, on which at least two adjacent metal wiring lines spaced from a gap are patterned. Each of the metal wiring lines may be formed from a variety of materials, such as aluminum, aluminum alloyed with silicon or copper, copper alloys, or refractory metals. Preferably, a cap layer of SiON is formed on the top of the metal wiring line to serve as a quarter wave plate, a hard mask and a protector. First, an oxide liner may be conformally deposited on the exposed surface of the metal wiring line and the semiconductor substrate by using plasma-enhanced chemical vapor deposition (PECVD). Then, a first dielectric layer, preferably of silicon oxide, is formed on the metal wiring lines to partially fill the gap below the level of the top of the metal wiring lines using high density plasma chemical vapor deposition (HDPCVD). Next, a second dielectric layer, preferably of silicon oxide, is formed on the first dielectric layer to completely fill the gap with a predetermined thickness by using PECVD. Thus, the first dielectric layer and the second dielectric layer between the two adjacent metal wiring lines serve as the IMD layer.

Accordingly, it is a principle object of the invention to provide means for forming the second dielectric layer with a preferred topography that is not sensitive to a subsequent CMP.

It is another object of the invention to improve the global planarization on the IMD layer after the subsequent CMP.

Yet another object of the invention is to prevent defects formed on the second dielectric layer during the CMP.

It is a further object of the invention to decrease the time during HDPCVD.

Still another object of the invention is to lower production cost and increase throughput by decreasing the time.

These and other objects of the present invention will become readily apparent upon further review of the following specification and drawings.

### BRIEF DESCRIPTION OF THE DRAWINGS

FIGS. 1A to 1D are cross-sectional diagrams showing a method of forming an IMD layer by a high density plasma chemical vapor deposition (HDPCVD) according to the prior art.

FIGS. 2A to 2H are cross-sectional diagrams showing a method of fabricating an IMD layer according to the first embodiment of the present invention.

FIGS. 3A and 3B are cross-sectional diagrams showing an IMD layer according to the second embodiment of the present invention.

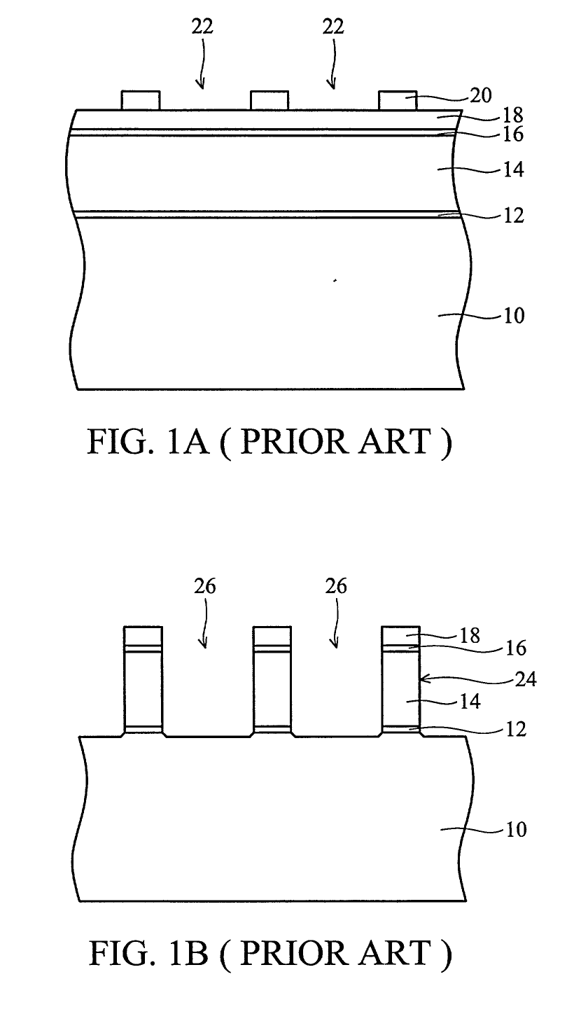

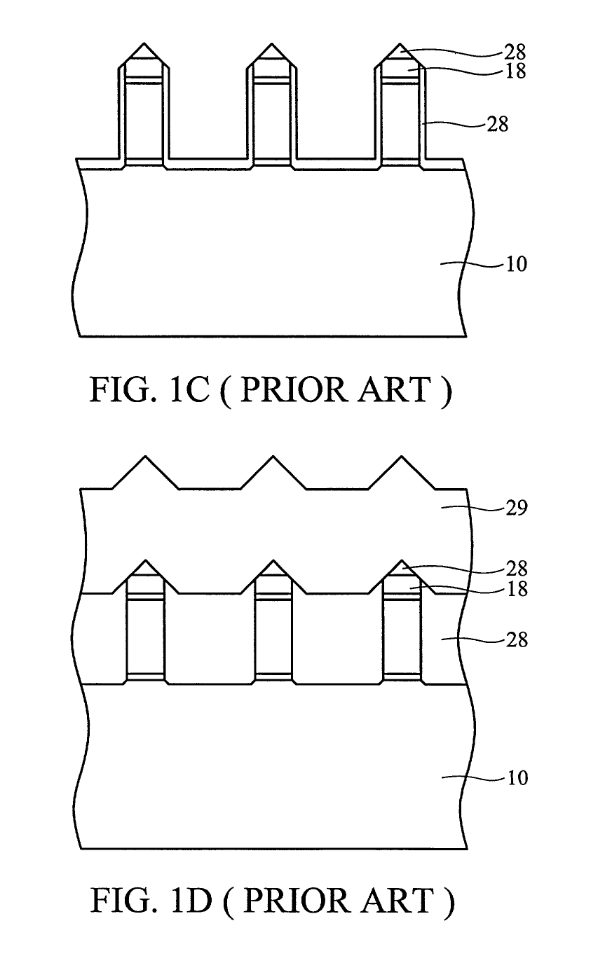

Similar reference characters denote corresponding features consistently throughout the attached drawings.

### DETAILED DESCRIPTION OF THE PREFERRED EMBODIMENTS

A method of fabricating an IMD layer is provided in order to improve global planarization in subsequent CMP. HDPCVD is employed to partially fill the gaps between metal wiring lines with a first dielectric layer, wherein the first dielectric layer deposited in the gaps is below the level of the top of the metal wiring lines. This can decrease process time and production costs, improving throughput. In addition, a sunken topography of the first dielectric layer is formed within the gap. When PECVD is then employed to form a second dielectric layer on the first dielectric layer to completely fill the gaps and reach a desired thickness, the top surface of the second dielectric layer appears as a flat topography of large areas and shallow sunken topography of small areas, thus tending to self-planarize. The pattern density of the topography of the second dielectric layer that becomes less sensitive to a subsequent CMP can improve the global planarization on the second dielectric layer after the subsequent CMP. Therefore, a planarized surface serving as a successive layer can be provided in subsequent processes, such as the formation of via holes and contact plugs.

[First Embodiment]

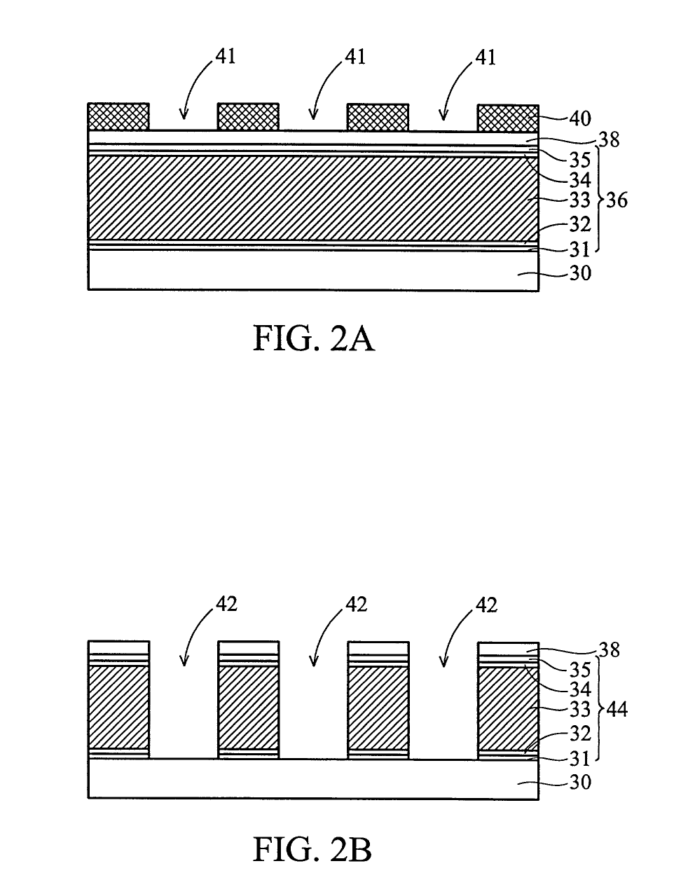

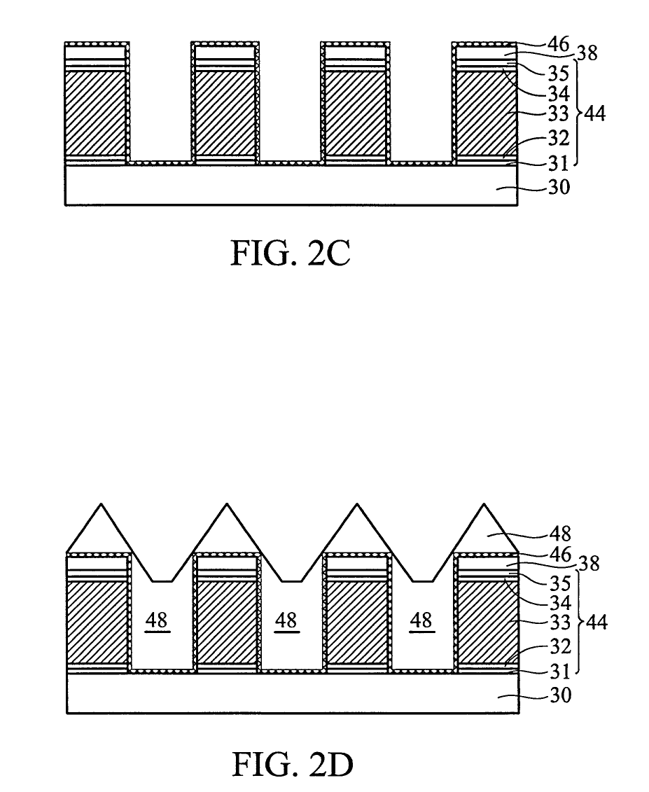

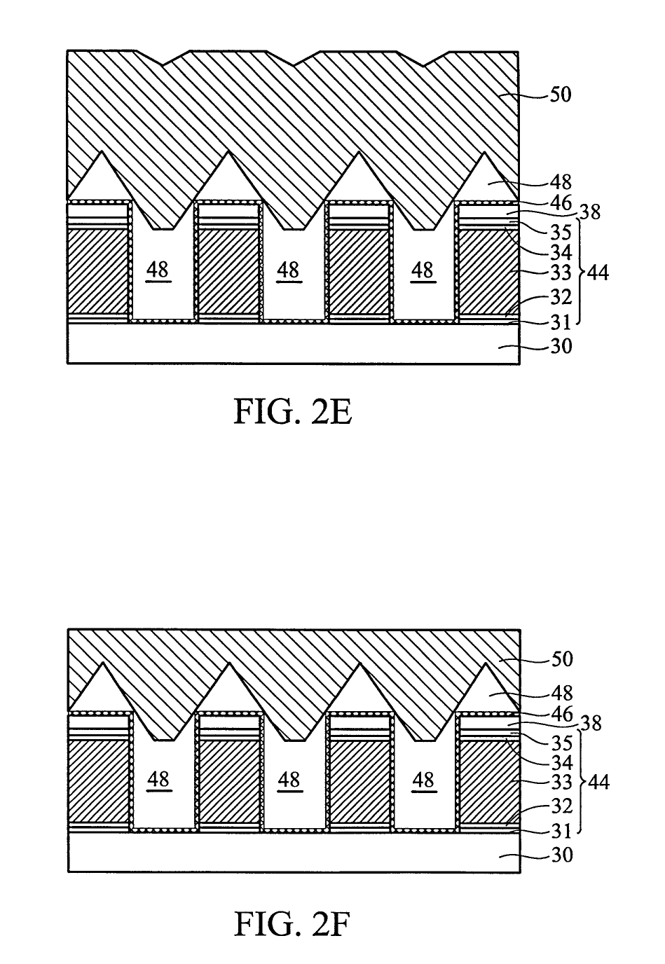

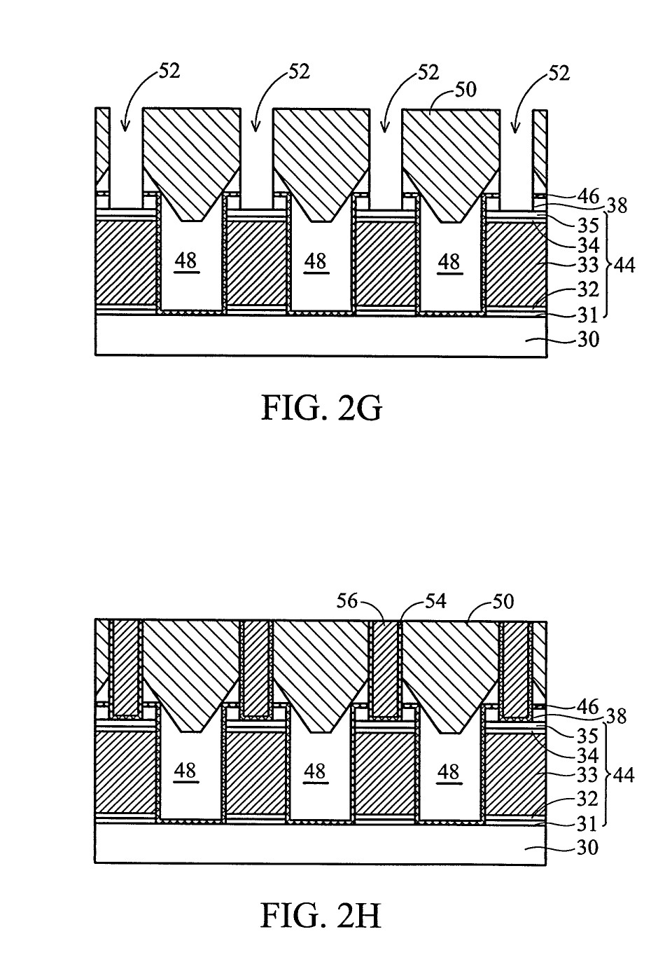

FIGS. 2A to 2H are cross-sectional diagrams showing a method of fabricating an IMD layer in the first embodiment of the present invention. As shown in FIG. 2A, a semiconductor substrate 30 is provided, possibly containing, for example, transistors, diodes, other semiconductor elements as well known in the art, and other metal interconnect layers. A metal wiring line layer 36 deposited on the semiconductor substrate 30 may be formed from a variety of materials, such as aluminum, aluminum alloyed with silicon or copper, copper alloys, and multilayer structures. Preferably, the metal wiring line layer 36 is of a multilayer structure which has a first Ti layer 31, a first TiN layer 32, a AlCu layer 33, a second Ti layer 34, and a second TiN layer 35 sequentially formed on the semiconductor substrate 30.

In addition, a cap layer 38 is formed on the wiring layer, and a photoresist layer 40 is patterned on the cap layer 38 to expose predetermined regions 41. The cap layer 38, preferably of SiON, may serve as a quarter wave plate during the exposure of the photoresist layer 40 in order to prevent light from passing through the cap layer 38 and prevent light from reflecting back up to the photoresist layer 40. Also, the cap layer 38 may serve as a hard mask for etching the metal wiring line layer 36 in subsequent etching. Furthermore, the cap layer 38 may serve as a protector to shield the top corner of individual metal wiring lines from etching during subsequent HDPCVD.

Referring to FIG. 2B, by consecutively etching the cap layer 38, the layers 31, 32, 33, 34 and 35, from the exposed regions 41, the metal wiring line layer 36 is patterned to become a plurality of individual metal wiring lines 44 spaced from a plurality of gaps 42. The photoresist layer 40 is then removed. Next, as shown in FIG. 2C, using a PECVD, a PECVD oxide liner 46 is conformally deposited on the entire surface of the semiconductor substrate 30. One purpose of the PECVD oxide liner 46 is to increase the adhesion between the metal wiring line 44 and an IMD layer formed in subsequent processes. The other purpose of the PECVD oxide liner 46 is to prevent the outgassing effect from the IMD layer formed in subsequent processes.

Referring to FIG. 2D, HDPCVD, at a sufficiently high etch-to-deposition ratio, is performed to form an HDPCVD oxide layer 48. Since the HDPCVD may accomplish both deposition and etching at the same time, a taper topography of the HDPCVD oxide layer 48 is produced over the cap layer 38. It is noticed that the HDPCVD oxide layer 48 partially fills each gap 42 below the level of the top of the metal wiring line 44 as indicated by the dotted line. This can save process time, thus reducing production costs and increasing throughput. In addition, since a sunken topography of the HDPCVD oxide layer 48 is formed within the gap 42, a deposition layer that tends to self-planarize can be formed in subsequent deposition.

Referring to FIG. 2E, using the PECVD process again, a PECVD oxide layer 50 is deposited on the entire surface of the HDPCVD oxide layer 48 to completely fill the gaps 42 and reach a predetermined thickness. The top surface of the PECVD oxide layer 50 displays a flat topography of large areas and shallow sunken topography of small areas, thus the pattern density of the topography of the PECVD oxide layer 50 that becomes less sensitive to a subsequent CMP. As shown in FIG. 2F, when a CMP is performed to planarize the top of the PECVD oxide layer 50, defects, such as dishing or corrosion effects on the PECVD oxide layer 50 can be prevented. Therefore, the uniformity of the PECVD oxide layer 50 is effectively improved after the CMP, and a global planarization layer is produced.

Hereinafter, a contact plug is provided on the planarized surface of the PECVD oxide layer 50. Contact plug fabrication methods are a design choice dependent on overall fabrication methods employed. Referring to FIG. 2G, using photolithography and etching, the PECVD oxide layer 50, the HDPCVD oxide layer 48, the PECVD oxide liner 46 and the cap layer 38 are consecutively removed to form a plurality of via holes 52 which expose the tops of the metal wiring lines 44 respectively. Referring to FIG. 2H, a barrier layer 54 of Ti, TiN, Ta or TaN is deposited on the sidewall and bottom of each via hole 52, and then a conductive layer 56 is deposited to fill the via holes 52. After performing CMP again, excess portions outside the level of the via hole 52 are removed, and the remaining part of the conductive layer 56 in the via hole 52 serves as a contact plug 56.

[Second Embodiment]

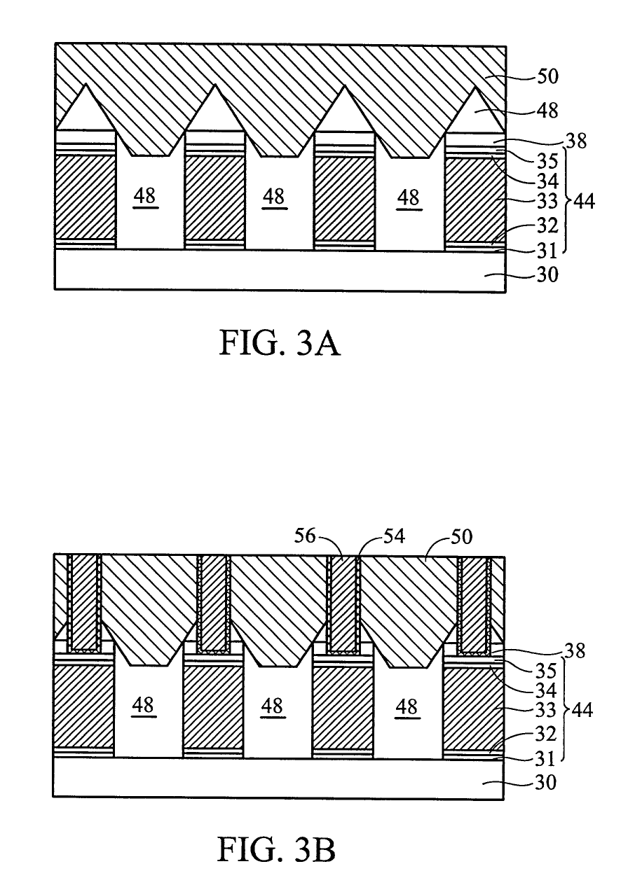

FIGS. 3A and 3B are cross-sectional diagrams showing an IMD layer according to the second embodiment of the present invention. The processes used in the fabrication of the metal wiring lines 44 and the cap layer 38 are substantially the same as those used in the first embodiment. Compared with the PECVD oxide liner 46 in the first embodiment, a HDPCVD oxide liner formed at the early stage of the HDPCVD replaces the PECVD oxide liner 46. In addition, a taper topography of the HDPCVD oxide layer 48 is produced over the cap layer 38. Then, HDPCVD is continually performed until each of the gaps 26 are partially filled with the HDPCVD oxide layer 48 below the level of the top of the metal wiring lines 44. Next, the processes used in the fabrication of the PECVD oxide layer 50, the via hole 52, the barrier layer 54 and the contact plug 56 are substantially the same as those used in the first embodiment.

It is to be understood that the present invention is not limited to the embodiments described above, but encompasses any and all embodiments within the scope of the following claims.

What is claimed is:

1. A method of fabricating an inter-metal dielectric (IMD) layer, comprising steps of:
providing a semiconductor substrate having at least two adjacent metal wiring lines separated by a gap;
forming a first dielectric layer on the metal wiring lines to partially fill the gap below the level of the top of the metal wiring lines using high density plasma chemical vapor deposition (HDPCVD); and
forming a second dielectric layer on the first dielectric layer to a predetermined thickness,
wherein the first dielectric layer and the second dielectric layer between the two adjacent metal wiring lines serve as the IMD layer.

2. The method according to claim 1, wherein the step of forming the second dielectric layer uses plasma-enhanced chemical vapor deposition (PECVD).

3. The method according to claim 1, wherein the first dielectric layer and the second dielectric layer are of silicon oxide.

4. The method according to claim 1, further comprising a step of forming an oxide liner on the exposed surface of the metal wiring lines and the semiconductor substrate prior to the formation of the first dielectric layer.

5. The method according to claim 4, wherein the step of forming the oxide liner uses plasma-enhanced chemical vapor deposition (PECVD).

6. The method according to claim 1, further comprising a step of performing chemical-mechanical polishing (CMP) to planarize the top of the second dielectric layer.

7. The method according to claim 6, further comprising a step of forming a via hole passing through the IMD layer and exposing the top of the metal wiring line.

8. The method according to claim 1, wherein the semiconductor substrate further comprises a cap layer on each top of the metal wiring lines.

9. The method according to claim 8, wherein the cap layer is SiON.

10. The method according to claim 1, wherein each of the metal wiring lines is formed from a variety of materials, such as aluminum, aluminum alloyed with silicon or copper, copper alloys, or refractory metals.
